(19) United States
(12) Patent Application Publication
(10) Pub. No.: US 2002/0186787 A1
(43) Pub. Date: Dec. 12, 2002

(54) Binary waveform divider

(76) Inventor: Michael Andrew Fischer, San Antonio, TX (US)

Correspondence Address: DEMONT & BREYER, LLC, PO BOX 7490, SHREWSBURY, NJ, 07702, US

(21) Appl. No.: 09/860,681

(22) Filed: May 19, 2001

(51) Int. Cl. H03K 9/00

(52) U.S. Cl. 375/316; 375/219

(57) ABSTRACT

A method of dividing a first binary waveform utilizing the occurrence of some, but not all, of the rising edges of the first binary waveform and some, but not all, of the falling edges of the first binary waveform. By choosing which rising edges and falling edges are used, the average cycle time and duty cycle of the second binary waveform can be selected. The illustrative embodiment of the present invention comprises: a waveform receiver for receiving a first binary waveform that comprises a plurality of rising edges and a plurality of falling edges; and a waveform generator for outputting a second binary waveform based on the first binary waveform, wherein the second binary waveform is toggled based on an odd number of rising edges between being toggled based on said falling edges.

### FIELD OF THE INVENTION

The present invention relates to digital circuit design in general and, more particularly, to a circuit capable of dividing a binary waveform (e.g., a clock signal, etc.) by a non-integral factor (e.g., 22/5, etc.).

### BACKGROUND OF THE INVENTION

FIG. 1 depicts a block diagram of waveform reduction circuitry 100 in the prior art, which divides the frequency or average cycle time of a first binary waveform (e.g., a clock signal, etc.) by some factor to create a second binary waveform. Typically, waveform reduction circuitry in the prior art uses phase-locked loops, delay-locked loops, counters, or multiple binary waveforms of different frequencies to accomplish the task. All of these approaches have disadvantages in particular applications, and, therefore, the need exists for more advantageous techniques for the division of binary waveforms.

### SUMMARY OF THE INVENTION

Some embodiments of the present invention are capable of dividing a binary waveform without some of the costs and disadvantages of binary waveform dividers in the prior art. In particular, the illustrative embodiment of the present invention utilizes a single binary waveform as input and can divide the first binary waveform by a non-integral factor (i.e., a mixed number) to generate a second binary waveform (i.e., the average cycle time of the first binary waveform is not an integral number of the average cycle time of the second binary waveform).

The illustrative embodiment of the present invention accomplishes this by toggling the second binary waveform based on the occurrence of some, but not all, of the rising edges of the first binary waveform and by toggling the second binary waveform based on the occurrence of some, but not all, of the falling edges of the first binary waveform. By appropriately choosing which rising edges and falling edges to use to toggle the second binary waveform, the characteristics (e.g., average cycle time, duty cycle, etc.) of the second binary waveform can be selected. For example, the illustrative embodiment can toggle the second binary waveform based on an odd number of rising edges between being toggled based on falling edges, and vice versa. This enables great flexibility in the design of the second binary waveform. For example, the illustrative embodiment of the present invention can in some cases generate a second binary waveform with a 50% duty cycle based on a first binary waveform that has other than a 50% duty cycle. And still furthermore, the illustrative embodiment of the present invention can in some cases generate a second binary waveform with other than a 50% duty cycle based on a first binary waveform with a 50% duty cycle.

The illustrative embodiment of the present invention comprises: a waveform receiver for receiving a first binary waveform that comprises a plurality of rising edges and a plurality of falling edges; and a waveform generator for outputting a second binary waveform based on the first binary waveform, wherein the second binary waveform is toggled based on an odd number of rising edges between being toggled based on said falling edges.

### BRIEF DESCRIPTION OF THE DRAWINGS

FIG. 1 depicts a block diagram of waveform reduction circuitry in the prior art.

FIG. 2 depicts a block diagram of the illustrative embodiment of the present invention.

FIG. 3 depicts a diagram of binary waveform 300 in accordance with the illustrative embodiment of the present invention.

FIG. 4 depicts a block diagram of waveform reduction circuitry 213 in accordance with the illustrative embodiment of the present invention.

FIG. 5 depicts a block diagram of the first illustrative embodiment of waveform receiver 401.

FIG. 6 depicts a block diagram of the second illustrative embodiment of waveform generator 401.

FIG. 7 depicts a block diagram of waveform generator 402.

FIG. 8 depicts a flowchart of the steps involved in determining the values of i, RE(x), for x=1 to i, k, and FE(y), for y=1 to k, for a first binary waveform and a second binary waveform.

FIG. 9 depicts graphically the relationship of the maximum jitter in the second binary waveform from some embodiments of the present invention as a function of the duty cycle of the first binary waveform.

FIG. 10 depicts the relative timing of the first binary waveform, the FFA enable on lead 411, the QA output of flip-flop 701, the FFB enable on lead 412, the QB output of flip-flop 702, and the second binary waveform.

### DETAILED DESCRIPTION

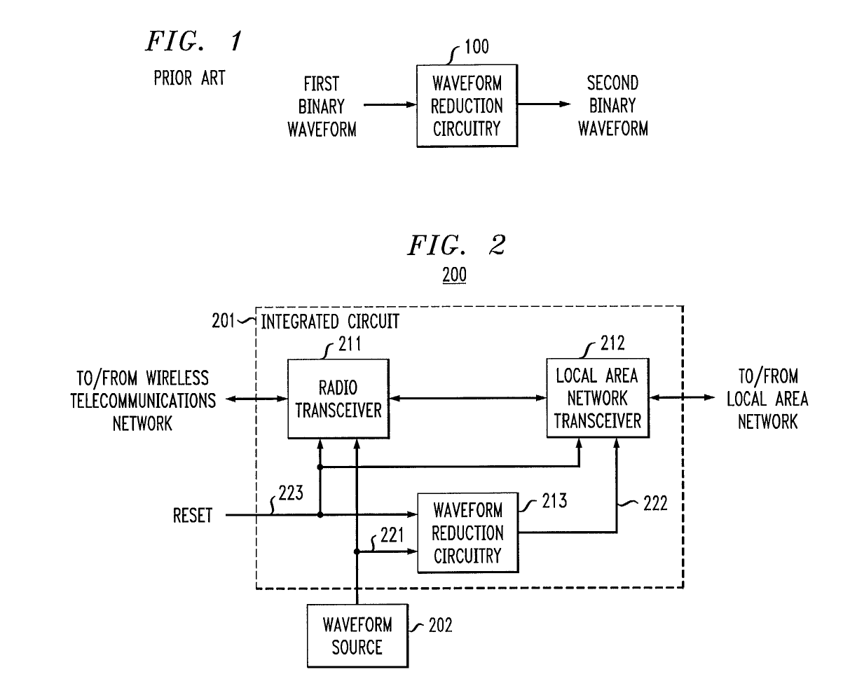

FIG. 2 depicts a block diagram of the illustrative embodiment of the present invention, which is contained entirely on integrated circuit 201. For the purpose of this specification, the term “integrated circuit” is defined as a slice or chip of material on which is etched or imprinted a complex of electronic components and their interconnections.

Integrated circuit 201 comprises: the baseband processor portion of radio transceiver 211 (i.e., the radio frequency front-end and transmit power amplifier are not on integrated circuit 201), local area network transceiver 212, and waveform reduction circuitry 213, interconnected as shown. In accordance with the illustrative embodiment, integrated circuit 201 functions as a bridge between a wireless telecommunications network (not shown), such as an IEEE 802.11 wireless local area network, and a wireline local area network (not shown), such as a IEEE 802.3 10Base-T network. Therefore, radio transceiver 211 receives information-bearing signals from the wireless telecommunications network and passes them to local area network transceiver 212 for transmission via the wireline local area network. Analogously, local area network transceiver 212 receives information-bearing signals from the wireline local area network and passes them to radio transceiver 211 for transmission via the wireless telecommunications network. It will be clear to those skilled in the art how to make and use radio transceiver 211 and local area network transceiver 212.

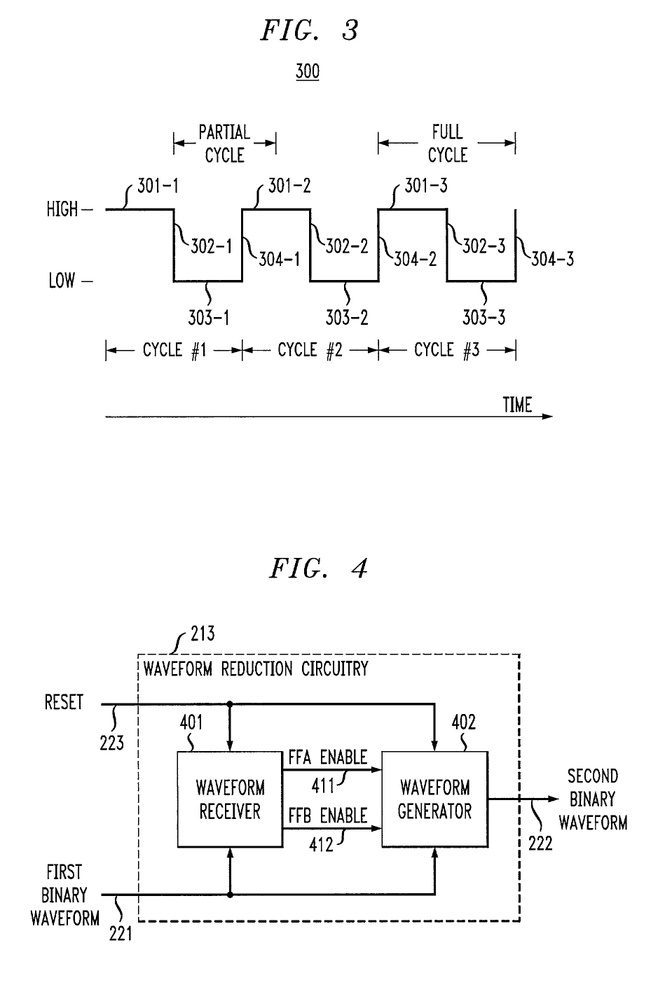

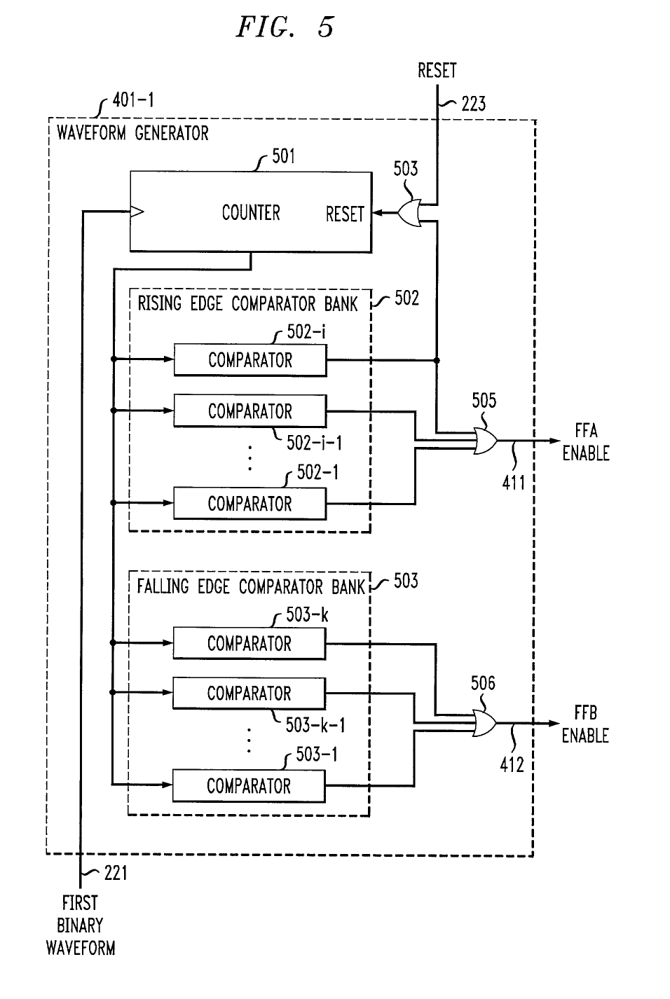

In accordance with the illustrative embodiment, radio transceiver 211 and local area network transceiver 212 each require a binary waveform (e.g., a “clock”) as a timing reference. For example, in accordance with IEEE 802.11, a direct sequence radio transceiver requires a 44 MHz binary waveform and an IEEE 802.3 10Base-T local area network transceiver requires a 10 MHz binary waveform. In accordance with the illustrative embodiment, waveform source 202 (e.g., an off-chip crystal oscillator, etc.) produces a first binary waveform on lead 221 at 44 MHz for radio transceiver 211 and waveform reduction circuitry 213 outputs a second binary waveform on lead 222 at 10 MHz for local area network transceiver 212 based on the first binary waveform. It will be clear to those skilled in the art how to make and use waveform source 202. Also in accordance with the illustrative embodiment, radio transceiver 211, local area network transceiver 212, and waveform reduction circuitry 213 all receive a reset signal on lead 223, which resets the operation of the illustrative embodiment. The reset signal will be described in detail below and with reference to FIGS. 4, 5, 6, and 7.

To facilitate an understanding of the present invention, the components of waveform reduction circuitry 213 are shown by the function that each performs. It will be clear to those skilled in the art how to make and use combinatorial and sequential logic to perform each of these functions. Furthermore, it will be clear to those skilled in the art how to make and use combinatorial and sequential logic that performs two or more functions or that partitions the functions in different ways than that shown in FIGS. 5, 6, and 7. For that reason, it will be clear to those skilled in the art how to make and use combinatorial and sequential logic that is within the scope of the following claims even though it might not resemble that shown in FIG. 5 or 6 or 7.

FIG. 3 depicts a diagram of binary waveform 300 in accordance with the illustrative embodiment of the present invention. Binary waveform 300 is a temporally-changing waveform that comprises a plurality of high values, 301-1 through 301-3, interspersed with a plurality of low values, 303-1 through 303-3. Each transition from high value 301-x to low value 303-x is characterized by falling edge 302-x and each transition from low value 303-x to high value 301-(x+1) is characterized by rising edge 304-x. Therefore, as can be seen in FIG. 4, a binary waveform is characterized by a repetitive cycle of high values, falling edges, low values, and rising edges. For the purposes of this specification, a “binary waveform” is defined as a repetitive cycle of high values, falling edges, low values, and rising edges.

Because the concept of a full cycle of a binary waveform is used within this specification to describe the illustrative embodiment, for the purposes of this specification, a “full cycle” of a binary waveform is defined as one complete high interval, one complete falling edge, one complete low interval, and one complete rising edge, all in succession. For the purposes of this specification, a “partial cycle” of a binary waveform is defined as less than one full cycle.

For the purposes of this specification, a each cycle in a binary waveform might be uniquely identified with a number and each cycle is defined to begin at the beginning of a high interval.

Because the concept of the duty cycle of a binary waveform is used within this specification to describe the illustrative embodiment, for the purposes of this specification, the “duty cycle” of a binary waveform is defined as the average amount of time that a binary waveform has a high value divided by the average amount of time that the binary waveform requires to complete a full cycle. Therefore, the duty of cycle of a binary waveform is constrained by:

0<duty cycle<1 (Eq. 1)

Because the concept of the average cycle time of a binary waveform is used within this specification to describe the illustrative embodiment, for the purposes of this specification, the “average cycle time” of a binary waveform is defined as the average amount of time that the binary waveform requires to complete a fill cycle.

FIG. 4 depicts a block diagram of waveform reduction circuitry 213 in accordance with the illustrative embodiment of the present invention. Waveform reduction circuitry 213 comprises waveform receiver 401 and waveform generator 402, interconnected as shown. As is described in greater detail below and with respect to FIGS. 5, 6, and 8, waveform receiver 401 receives the reset signal and the first binary waveform and determines:

1. which rising edges of the first binary waveform should be used to toggle the second binary waveform, and

2. which falling edges of the first binary waveform should be used to toggle the second binary waveform.

In accordance with the illustrative embodiment of the present invention, the second binary waveform is driven high based on the occurrence of some of, but less than all of, the rising edges and on some of, but less than all of, the falling edges, and the second binary waveform is driven low based on the occurrence of some of, but less than all of, the rising edges and on some of, but less than all of, the falling edges.

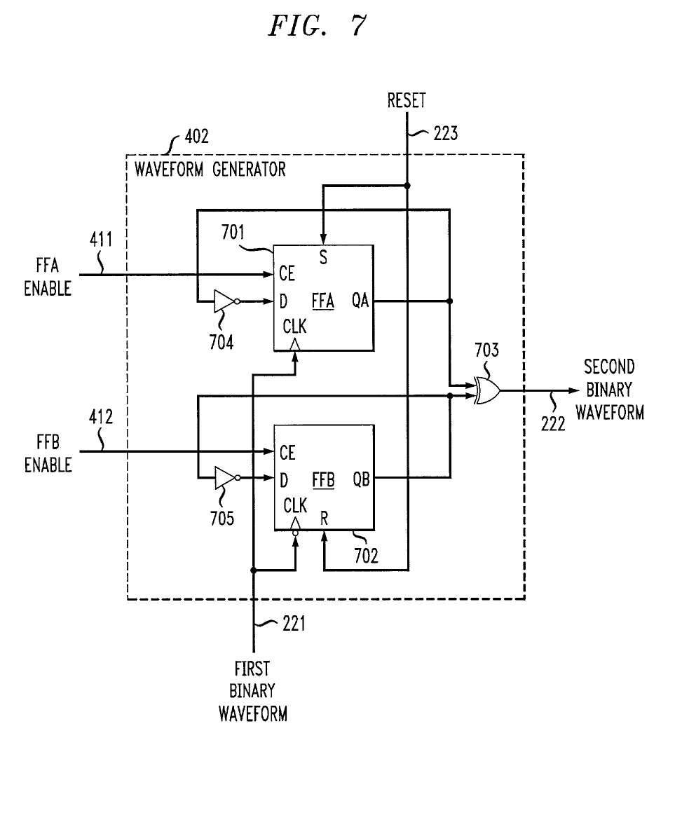

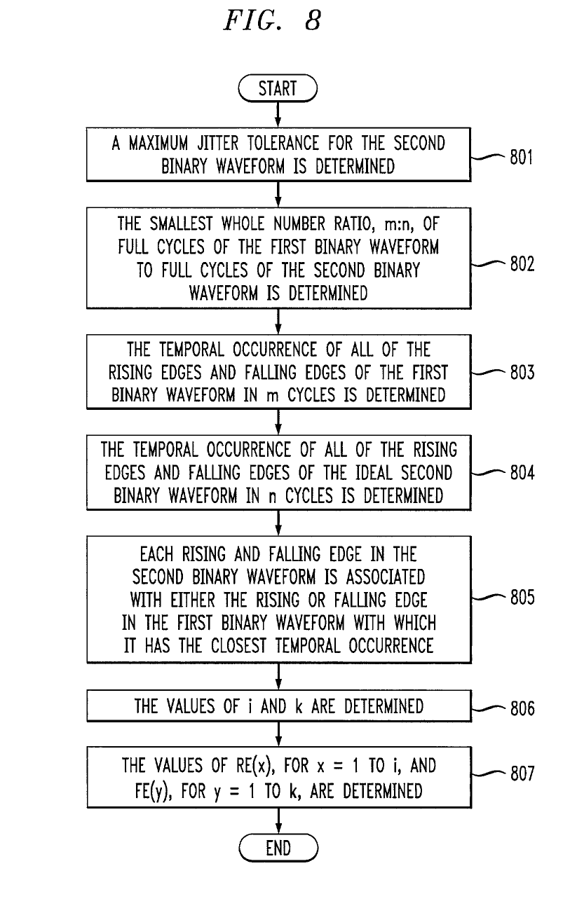

As is described in greater detail below and with respect to FIGS. 7 and 8, waveform generator 402 receives the reset signal and the first binary waveform and toggles the second binary waveform at occasions dictated by waveform receiver 401, the reset signal, and the first binary waveform.

FIG. 5 depicts a block diagram of the first illustrative embodiment of waveform receiver 401. Waveform receiver 401-1 comprises: counter 501, rising edge comparator bank 502, falling edge comparator bank 503, boolean OR gate 504, boolean OR gate 505, and boolean OR gate 506, interconnected as shown.

As recited above, these elements represent the functions performed by waveform receiver 401-1, and it will be clear to those skilled in the art how to make and use combinatorial and sequential logic to emulate waveform receiver 401-1 and that is within the scope of the following claims and yet does not resemble the circuitry shown in FIG. 5. For example, it will be clear to those skilled in the art how to make and use combinatorial logic that efficiently combined all of the comparators in a comparator bank.

Counter 501 is an M-bit straight-binary up counter with a synchronous reset that resets the counter to zero. The value of M is determined by:

M=└log₂(m−1)┘+1 (Eq. 2)

The procedure for determining the value of m is described below and with respect to FIG. 8. After each rising edge on the first binary waveform, counter 501 increments by one. The output of counter 501 is output to each comparator in rising edge comparator bank 502 and to each comparator in falling edge comparator bank 503.

Rising edge comparator bank 502 comprises logic that emulates i comparators, comparators 502-1 through 502-i, wherein i is a positive integer. The procedure for determining the value of i is described below and with respect to FIG. 8. Comparator 502-x, for x=1 to i, compares the output of counter 501 to a value, RE(x), and outputs a high value only when the output of counter 501 equals RE(x). The procedure for determining the values of RE(x), for x=1 to i, is described below and with respect to FIG. 8. The purpose of rising edge comparator bank 502 is to indicate to waveform generator 402 on which rising edges, RE(x), for x=1 to i, of the first binary waveform generator 402 is to toggle the second binary waveform.

The outputs of rising edge comparator bank are input to boolean OR gate 505, which creates the FFA enable signal on lead 411 for waveform generator 402.

The output of comparator 502-i, which compares the output of counter 501 to RE(i), is also input to boolean OR gate 504, which forms the composite reset signal for counter 501. The purpose of this feedback loop is to ensure that when counter 501 reaches a value of RE(i), it resets itself back to zero after the next rising edge of the first binary waveform.

Falling edge comparator bank 503 comprises logic that emulates k comparators, comparators 503-1 through 503-k, wherein k is a positive integer. The procedure for determining the value of k is described below and with respect to FIG. 8. Comparator 503-y, for y=1 to k, compares the output of counter 501 to a value, FE(y), and outputs a high value only when the output of counter 501 equals FE(y). The procedure for determining the values of FE(y), for y=1 to k, is described below and with respect to FIG. 8. The purpose of falling edge comparator bank 502 is to indicate to waveform generator 402 on which falling edges, FE(y), for y=1 to k, of the first binary waveform generator 402 is to toggle the second binary waveform The outputs of falling edge comparator bank are input to boolean OR gate 506, which creates the FFB enable signal on lead 412 for waveform generator 402.

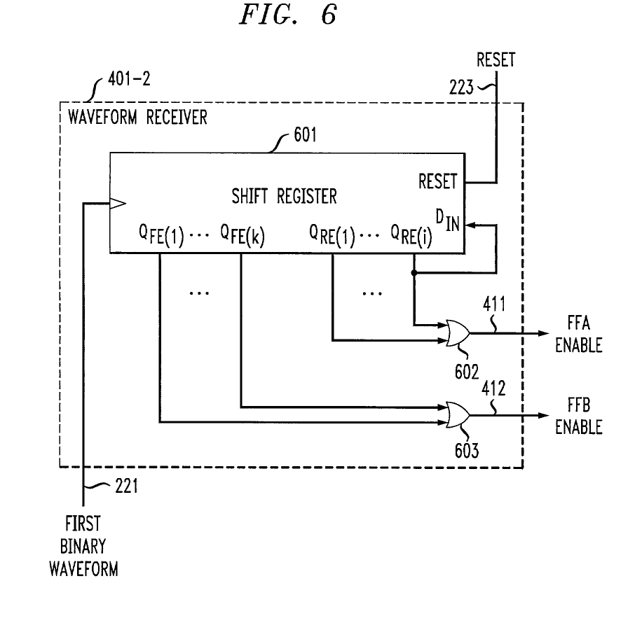

FIG. 6 depicts a block diagram of the second illustrative embodiment of waveform generator 401. Waveform receiver 402-2 comprises: shift register 601, boolean OR gate 602, and boolean OR gate 603, interconnected as shown.

Shift register 601 is an m-bit shift register with a synchronous reset that resets all of the cells, Q₁ through Qₘ₋₁, low except for cell Q₀, which is set high. After each rising edge on the first binary waveform, shift register 601 shifts the contents of cell Qₐ into cell Qₐ₊₁, for a=0 to m-2, and the output of cell Qₘ₋₁ into cell Q₀.

The output of some of the cells, cells Q_{RE(x)}, for x=1 to i, are input to boolean OR gate 505, which creates the FFA enable signal on lead 411 for waveform generator 402. The procedure for determining the values of i and of RE(x), for x=1 to i, are described below and with respect to FIG. 8. The purpose of cells Q_{RE(x)}, for x=1 to i, and boolean OR gate 505 is to indicate to waveform generator 402 to toggle the second binary waveform on rising edges RE(x), for x=1 to i, of the first binary waveform.

The output of some of the cells, cells Q_{FE(y)}, for y=1 to k, are input to boolean OR gate 506, which creates the FFB enable signal on lead 412 for waveform generator 402. The procedure for determining the values of k and of FE(y), for y=1 to k, are described below and with respect to FIG. 8. The purpose of cells Q_{FE(y)}, for y=1 to k, and boolean OR gate 506 is to indicate to waveform generator 402 to toggle the second binary waveform on falling edges FE(y), for y=1 to k, of the first binary waveform.

When the ratio of full cycles of the first binary waveform to full cycles of the second binary waveform is 22:5, as it is in the illustrative embodiment which generates a 10 MHz second binary waveform from a 44 MHz first binary waveform, waveform generator 401-1 in FIG. 5 is preferred over waveform generator 401-2 in FIG. 6. This is because the logic complexity of waveform generator 401-1 is approximately 68 gates (2-input NAND equivalent) and 7 edge-triggered flip-flops, whereas the logic complexity of waveform generator 401-2 in FIG. 6 is approximately 12 gates (2-input NAND equivalent) and 24 edge-triggered flip-flops. Therefore, the 56 extra gates needed in waveform generator 401-1 will consume less space and power than the 17 extra flip-flops needed in waveform generator 401-2.

FIG. 7 depicts a block diagram of waveform generator 402, which comprises: flip-flop 701, flip-flop 702, boolean Exclusive-OR gate 703, inverter 704, and inverter 705, interconnected as shown.

Flip-flop 701 is a rising-edge triggered flip-flop with a clock enable input, CE, fed by FFA enable on lead 411, an input fed by inverter 704, and a set input, S. The output of flip-flop 701, QA, is fed into boolean Exclusive-OR gate 703 and into inverter 704.

Flip-flop 702 is a falling-edge triggered flip-flop with a clock enable input, CE, fed by FFB enable on lead 412, an input fed by inverter 705, and a reset input, R. The output of flip-flop 702, QB, is fed into boolean Exclusive-OR gate 703 and into inverter 705.

It will be clear to those skilled in the art that some embodiments of the present invention can be fabricated with other circuitry (e.g., flip-flop 701 and 702 can be fabricated with J-K and T-type flip-flops, etc.)

The output of boolean Exclusive-OR gate 703 is the second binary waveform on lead 222. The purpose of boolean Exclusive-OR gate 703 is to toggle the second binary waveform when directed to by waveform receiver 401 (as indicated by the FFA enable and the FFB enable) based on the occurrence of some, but not all, of the rising edges and on the occurrence of some, but not all of, the falling edges of the first binary waveform.

FIG. 8 depicts a flowchart of the steps involved in determining the values of i, RE(x), for x 1 to i, k, and FE(y), for y=1 to k, for a first binary waveform and a second binary waveform. Although the steps depicted in FIG. 8 are generic and apply to any first binary waveform and any second binary waveform, to facilitate an understanding of the present invention each step is explained as it is applied to the illustrative embodiment in which the first binary waveform is 44 MHz with a 50% duty cycle and the second binary waveform is 10 MHz.

At step 801, a maximum jitter tolerance for the second binary waveform is determined. To accomplish this, the desired duty cycle of the second binary waveform is determined. For the purposes of this specification, the duty cycle of the first binary waveform is defined as a, wherein 0<a <1. Furthermore, for the purposes of this specification, the desired duty cycle of the second binary waveform is defined as b_{d}, wherein 0<b_{d}<1.

Although the average cycle time of the second binary waveform can be set to an arbitrary value based on the average cycle time of the first binary waveform, embodiments of the present invention will not always generate a second binary waveform with a b_{d} duty cycle. Therefore, in some embodiments of the present invention, the second binary waveform can exhibit jitter. For the purposes of this specification, the term “jitter” is defined as the variance of when a rising edge or falling edge occurs relative to its nominal position in a binary waveform with a b_{d} duty cycle. Furthermore, for the purposes of this specification, the actual duty cycle of the second binary waveform is defined as bₐ, wherein 0<bₐ<1.

It will be clear to those skilled in the art how to determine what the maximum jitter tolerance for the second binary waveform is depending on the particular application. For example, for compatibility with the IEEE 802.3 10Base-T specification, the tolerable jitter is 5 nanoseconds.

Depending on the average cycle time and duty cycle of the first binary waveform, an embodiment of the present invention might or might not be able to generate a second binary waveform within the desired maximum jitter tolerance. For example, some embodiments of the present invention can satisfy a maximum jitter tolerance less than the average cycle time of the first binary waveform divided by four, assuming that the first binary waveform has a 50% duty cycle.

Because the amount of jitter of the second binary waveform is affected by the duty cycle of the first binary waveform, some embodiments of the present invention can satisfy a maximum jitter tolerance, for a waveform with a d duty cycle, of less than the larger of:

d times the average cycle time of the first binary waveform divided by two, and

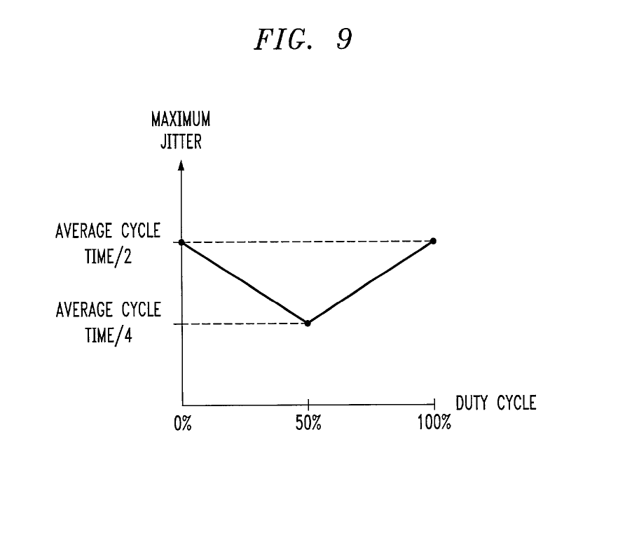

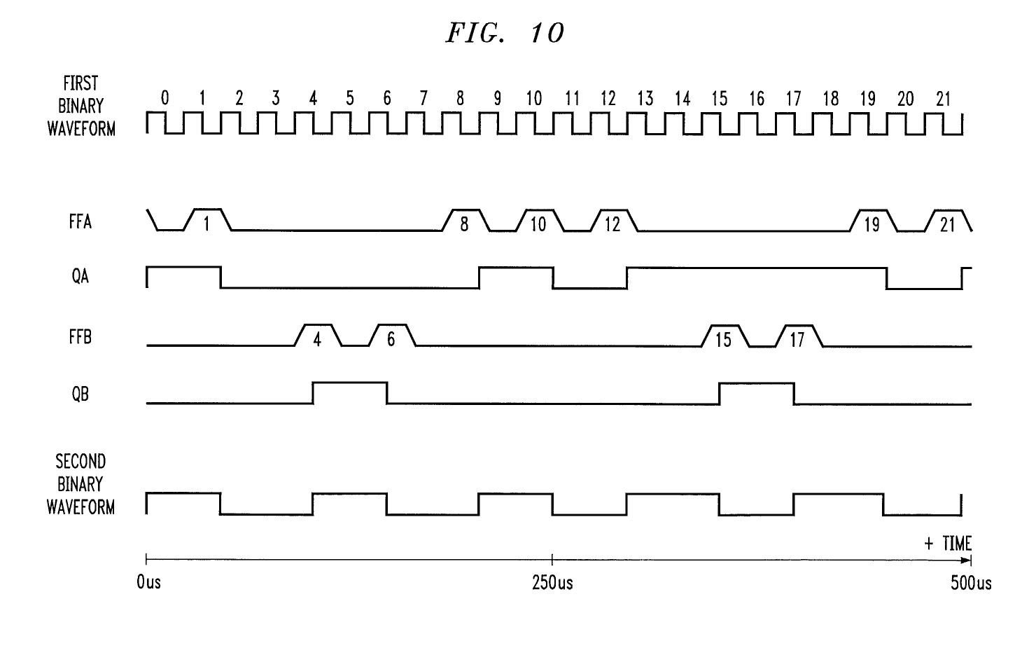

(1−d) times the average cycle time of the first binary waveform divided by two. FIG. 9 depicts graphically the relationship of the maximum jitter in the second binary waveform from some embodiments of the present invention as a function of the duty cycle of the first binary waveform Therefore, some embodiments of the present invention can generate a second binary waveform with a maximum jitter equal to or less than that shown in FIG. 9.

In accordance with the illustrative embodiment of the present invention, the first binary waveform has a 50% duty cycle and an average cycle time of 22.73 nanoseconds, and, therefore, the 5 nanoseconds maximum jitter tolerance of the 10Base-T specification is within the 5.68 (i.e., 22.73/4) nanosecond maximum jitter offered by the illustrative embodiment.

At step 802, the smallest whole number ratio, m:n, of full cycles of the first binary waveform to full cycles of the second binary waveform is determined. Perhaps the easiest way to compute this is by determining the ratio of the average frequency of the first binary waveform to the average frequency of the second binary waveform. In the illustrative embodiment, the average frequency of the first binary waveform is 44 MHz and the average frequency of the second binary waveform is 10 MHz. Therefore, the ratio is:

44 MHz: 10MHz (Eq. 2)

which reduces to:

22:5 (Eq. 3)

Therefore m=22 and n=5, wherein m and n are whole numbers and at least one of m and n is prime.

At step 803, the temporal occurrence of all of the rising edges and falling edges of the first binary waveform with an a duty cycle in m cycles is determined. Table 1 depicts the temporal occurrence of all of the rising edges and falling edges of a 44 MHz first binary waveform with a 50% duty cycle in 22 cycles.

At step 804, the temporal occurrence of all of the rising edges and falling edges of the ideal second binary waveform with a b_{d} duty cycle in n cycles is determined. Table 2 depicts the temporal occurrence of all of the rising edges and falling edges of a 10 MHz second binary waveform with a 50% duty cycle in 5 cycles.

At step 805, each rising and falling edge in the second binary waveform is associated with either the rising or falling edge in the first binary waveform with which it has the closest temporal occurrence. Table 3 depicts the closest association of each of the 10 edges of the second binary waveform with the 10 of 44 rising or falling edges in the first binary waveform.

As can be seen from Table 3, the maximum predicted jitter is 4.5 nanoseconds, which is within the 5.68 nanosecond maximum jitter window determined in step 801.

At step 806, the values of i and k are determined. In accordance with the illustrative embodiment, the value of i equals the number of rising edges of the first binary waveform associated with an edge (any edge) in the second binary waveform. From Table 3 it can be observed that there are six rising edges in the first binary waveform (at 45.5, 204.5, 250.0, 295.5, 454.5 and 500.0 ns) associated with an edge in the second binary waveform, and, therefore, i=6.

In accordance with the illustrative embodiment, the value of k equals the number of falling edges of the first binary waveform associated with an edge (any edge) in the second binary waveform. From Table 3 it can be observed that there are four falling edges in the first binary waveform (at 102.3, 147.7, 352.3, and 397.7 ns) associated with an edge in the second binary waveform, and, therefore, k=4.

At step 807, the values of RE(x), for x=1 to i, and FE(y), for y=1 to k, are determined. RE(x) is equal to the cycle number associated with the xth rising edge in the first binary waveform associated with an edge in the second binary waveform. These numbers can be obtained from Table 3. Table 4 depicts the values for RE(x), for x=1 to i, in accordance with the illustrative embodiment of the present invention.

Analogously, FE(y) is equal to the cycle number associated with the yth falling edge in the first binary waveform associated with an edge in the second binary waveform. These numbers can be obtained from Table 3. Table 5 depicts the values for FE(y), for y=1 to k, in accordance with the illustrative embodiment of the present invention.

Once the values of i, RE(x), for x=1 to i, k, and FE(y), for y=1 to k, for a first binary waveform and a second binary waveform are determined, waveform receiver 401 can be made and used in well-known fashion.

FIG. 10 depicts the relative timing of the first binary waveform, the FFA enable on lead 411, the QA output of flip-flop 701, the FFB enable on lead 412, the QB output of flip-flop 702, and the second binary waveform.

TABLE 1
Temporal Occurrence of All Edges in First Binary Waveform in m cycles.

| Cycle | Rising Edge | Falling Edge |
|---|---|---|
| # | (nanoseconds) | (nanoseconds) |
| 0 | | 11.4 |
| 0 | 22.7 | |
| 1 | | 34.1 |
| 1 | 45.5 | |
| 2 | | 56.8 |
| 2 | 68.2 | |
| 3 | | 79.6 |
| 3 | 90.9 | |
| 4 | | 102.3 |
| 4 | 113.6 | |
| 5 | | 125.0 |
| 5 | 136.4 | |
| 6 | | 147.7 |
| 6 | 159.1 | |
| 7 | | 170.5 |
| 7 | 181.8 | |
| 8 | | 193.2 |
| 8 | 204.6 | |
| 9 | | 215.9 |
| 9 | 227.3 | |
| 10 | | 238.6 |
| 10 | 250.0 | |
| 11 | | 261.4 |
| 11 | 272.7 | |
| 12 | | 284.1 |
| 12 | 295.5 | |
| 13 | | 306.8 |
| 13 | 318.2 | |
| 14 | | 329.6 |
| 14 | 340.9 | |
| 15 | | 352.3 |
| 15 | 363.6 | |
| 16 | | 375.0 |
| 16 | 386.4 | |
| 17 | | 397.7 |
| 17 | 409.1 | |
| 18 | | 420.5 |
| 18 | 431.8 | |
| 19 | | 443.2 |
| 19 | 454.6 | |
| 20 | | 465.9 |
| 20 | 477.3 | |
| 21 | | 488.6 |
| 21 | 500.0 | |

TABLE 2
Temporal Occurrence of All Edges in Second Binary
Waveform in n cycles.

| | Rising Edge | Falling Edge |
|---|---|---|
| Cycle # | (nanoseconds) | (nanoseconds) |
| 0 | | 50.0 |
| 0 | 100.0 | |
| 1 | | 150.0 |
| 1 | 200.0 | |
| 2 | | 250.0 |
| 2 | 300.0 | |
| 3 | | 350.0 |
| 3 | 400.0 | |
| 4 | | 450.0 |
| 4 | 500.0 | |

Table 3 appears on the page.

TABLE 4
Values of RE(x), for x = 1 to 6

| x | x RE(x) |
|---|---|
| 1 | 1 |
| 2 | 8 |
| 3 | 10 |
| 4 | 12 |
| 5 | 19 |
| 6 | 21 |

TABLE 5
Values of FE(x), for x = 1 to 4

| y | FE(y) |
|---|---|
| 1 | 4 |
| 2 | 6 |
| 3 | 15 |
| 4 | 17 |

TABLE 3
Association of Edges in First and Second Binary Waveforms

| | Rising Edge of | Falling Edge of | | |
|---|---|---|---|---|
| | First Binary | First Binary | Second Binary | |
| Cycle | Waveform | Waveform | Waveform Edge | Predicted |
| # | (ns) | (ns) | (ns) | Jitter (ns) |
| 0 | | 11.4 | | |
| 0 | 22.7 | | | |
| 1 | | 34.1 | | |
| 1 | 45.5 | | 50.0 | −4.5 |
| 2 | | 56.8 | | |
| 2 | 68.2 | | | |
| 3 | | 79.6 | | |
| 3 | 90.9 | | | |
| 4 | | 102.3 | 100.0 | +2.3 |
| 4 | 113.6 | | | |
| 5 | | 125.0 | | |
| 5 | 136.4 | | | |
| 6 | | 147.7 | 150.0 | −2.3 |
| 6 | 159.1 | | | |
| 7 | | 170.5 | | |
| 7 | 181.8 | | | |
| 8 | | 193.2 | | |
| 8 | 204.5 | | 200.0 | +4.5 |
| 9 | | 215.9 | | |
| 9 | 227.3 | | | |
| 10 | | 238.6 | | |
| 10 | 250.0 | | 250.0 | 0.0 |
| 11 | | 261.4 | | |
| 11 | 272.7 | | | |
| 12 | | 284.1 | | |
| 12 | 295.5 | | 300.0 | −4.5 |
| 13 | | 306.8 | | |
| 13 | 318.2 | | | |
| 14 | | 329.6 | | |
| 14 | 340.9 | | | |
| 15 | | 352.3 | 350.0 | +2.3 |
| 15 | 363.6 | | | |
| 16 | | 375.0 | | |
| 16 | 386.4 | | | |
| 17 | | 397.7 | 400.0 | −2.3 |
| 17 | 409.1 | | | |
| 18 | | 420.5 | | |
| 18 | 431.8 | | | |
| 19 | | 443.2 | | |
| 19 | 454.5 | | 450.0 | +4.5 |
| 20 | | 465.9 | | |
| 20 | 477.3 | | | |
| 21 | | 488.6 | | |
| 21 | 500.0 | | 500.0 | 0.0 |

It is to be understood that the above-described embodiments are merely illustrative of the present invention and that many variations of the above-described embodiments can be devised by those skilled in the art without departing from the scope of the invention. It is therefore intended that such variations be included within the scope of the following claims and their equivalents.

What is claimed is:

1. An apparatus comprising:
a waveform receiver for receiving a first binary waveform that comprises a plurality of rising edges and a plurality of falling edges; and
a waveform generator for outputting a second binary waveform based on said first binary waveform, wherein said second binary waveform is toggled based on an odd number of rising edges between being toggled based on said falling edges.

2. The apparatus of claim 1 wherein said second binary waveform is toggled based on an odd number of falling edges between being toggled based on said rising edges.

3. The apparatus of claim 1 wherein the ratio of full cycles of said first binary waveform to full cycles of said second binary waveform is m:n, and wherein m and n are whole numbers and at least one of m and n is prime.

4. The apparatus of claim 1 wherein said second binary waveform is toggled based on at least three rising edges between being toggled based on said falling edges.

5. The apparatus of claim 1 wherein said first binary waveform has an average cycle time of 22.7 nanoseconds and said second binary waveform has an average cycle time of 100.0 nanoseconds.

6. The apparatus of claim 1 further comprising a wireline local area network transceiver for receiving said second binary waveform for use as a timing reference.

7. The apparatus of claim 1 further comprising a radio transceiver for receiving said first binary waveform for use as a timing reference.

8. An apparatus comprising:
a waveform receiver for receiving a first binary waveform that comprises a plurality of rising edges and a plurality of falling edges; and
a waveform generator for outputting a second binary waveform based on said first binary waveform, wherein said second binary waveform is toggled based on an odd number of falling edges between being toggled based on said rising edges.

9. The apparatus of claim 8 wherein said second binary waveform is toggled based on an odd number of rising edges between being toggled based on said falling edges.

10. The apparatus of claim 8 wherein the ratio of full cycles of said first binary waveform to full cycles of said second binary waveform is m:n, and wherein m and n are whole numbers and at least one of m and n is prime.

11. The apparatus of claim 8 wherein said second binary waveform is toggled based on at least three falling edges between being toggled based on said falling edges.

12. The apparatus of claim 8 wherein said first binary waveform has an average cycle time of 22.7 nanoseconds and said second binary waveform has an average cycle time of 100.0 nanoseconds.

13. The apparatus of claim 8 further comprising a wireline local area network transceiver for receiving said second binary waveform for use as a timing reference.

14. The apparatus of claim 8 further comprising a radio transceiver for receiving said first binary waveform for use as a timing reference.

15. An integrated circuit comprising:
a waveform receiver for receiving a first binary waveform that comprises a plurality of rising edges and a plurality of falling edges; and
a waveform generator for outputting a second binary waveform based on said first binary waveform, wherein said second binary waveform is toggled based on an odd number of rising edges between being toggled based on said falling edges.

16. The integrated circuit of claim 15 wherein said second binary waveform is toggled based on an odd number of falling edges between being toggled based on said rising edges.

17. The integrated circuit of claim 15 wherein the ratio of full cycles of said first binary waveform to full cycles of said second binary waveform is m:n, and wherein m and n are whole numbers and at least one of m and n is prime.

18. The integrated circuit of claim 15 wherein said second binary waveform is toggled based on at least three rising edges between being toggled based on said falling edges.

19. The integrated circuit of claim 15 wherein said first binary waveform has an average cycle time of 22.7 nanoseconds and said second binary waveform has an average cycle time of 100.0 nanoseconds.

20. The integrated circuit of claim 15 further comprising a wireline local area network transceiver for receiving said second binary waveform for use as a timing reference.

21. The integrated circuit of claim 15 further comprising a radio transceiver for receiving said first binary waveform for use as a timing reference.

22. An integrated circuit comprising:
a waveform receiver for receiving a first binary waveform that comprises a plurality of rising edges and a plurality of falling edges; and
a waveform generator for outputting a second binary waveform based on said first binary waveform, wherein said second binary waveform is toggled based on an odd number of falling edges between being toggled based on said rising edges.

23. The integrated circuit of claim 22 wherein said second binary waveform is toggled based on an odd number of rising edges between being toggled based on said falling edges.

24. The integrated circuit of claim 22 wherein the ratio of full cycles of said first binary waveform to full cycles of said second binary waveform is m:n, and wherein m and n are whole numbers and at least one of m and n is prime.

25. The integrated circuit of claim 22 wherein said second binary waveform is toggled based on at least three falling edges between being toggled based on said falling edges.

26. The integrated circuit of claim 22 wherein said first binary waveform has an average cycle time of 22.7 nanoseconds and said second binary waveform has an average cycle time of 100.0 nanoseconds.

27. The integrated circuit of claim 22 further comprising a wireline local area network transceiver for receiving said second binary waveform for use as a timing reference.

28. The integrated circuit of claim 22 further comprising a radio transceiver for receiving said first binary waveform for use as a timing reference.
